(19) United States
(12) Patent Application Publication
(10) Pub. No.: US 2010/0227443 A1
(43) Pub. Date: Sep. 9, 2010

(54) METHOD OF FORMING POLYCRYSTALLINE SILICON LAYER

(75) Inventors: Kil-Won LEE, Yongin-city (KR); Ki-Yong Lee, Yongin-city (KR); Jin-Wook Seo, Yongin-city (KR); Tae-Hoon Yang, Yongin-city (KR); Byoung-Keon Park, Yongin-city (KR); Maxim Lisachenko, Suwon-si (KR); Ji-Su Ahn, Yongin-city (KR); Young-Dae Kim, Yongin-city (KR); Sang-Yon Yoon, Yongin-city (KR); Jong-Ryuk Park, Yongin-city (KR); Bo-Kyung Choi, Yongin-city (KR); Yun-Mo Chung, Yongin-city (KR); Min-Jae Jeong, Yongin-city (KR); Jong-Won Hong, Yongin-city (KR); Heung-Yeol Na, Yongin-city (KR); Eu-Gene Kang, Yongin-city (KR); Seok-Rak Chang, Yongin-city (KR)

Correspondence Address: STEIN MCEWEN, LLP, 1400 EYE STREET, NW, SUITE 300, WASHINGTON, DC, 20005, US

(73) Assignee: Samsung Mobile Display Co., Ltd., Yongin-city (KR)

(21) Appl. No.: 12/713,928

(22) Filed: Feb. 26, 2010

(30) Foreign Application Priority Data
Mar. 5, 2009 (KR) 10-2009-0018928

(51) Int. Cl. H01L 21/336; H01L 21/20

(52) U.S. Cl. 438/166; 438/486; 257/E21.413; 257/E21.133

(57) ABSTRACT

A method of forming a polycrystalline silicon layer includes forming an amorphous silicon layer on a substrate by chemical vapor deposition using a gas including a silicon atom and hydrogen gas, and crystallizing the amorphous silicon layer into a polycrystalline silicon layer using a crystallization-inducing metal. The resultant polycrystalline silicon layer has an improved charge mobility.

### CROSS-REFERENCE TO RELATED APPLICATION

This application claims the benefit of Korean Patent Application No. 10-2009-0018928, filed Mar. 5, 2009, in the Korean Intellectual Property Office, the disclosure of which is incorporated herein by reference.

### BACKGROUND OF THE INVENTION

1. Field of the Invention

Aspects of the present invention relate to a method of forming a polycrystalline silicon layer, and more particularly, to a method of forming a polycrystalline silicon layer from an amorphous silicon layer formed using hydrogen gas as a carrier gas, and thus charge mobility of the polycrystalline silicon layer can be improved.

2. Description of the Related Art

Generally, polycrystalline silicon layers are widely used as semiconductor layers for thin film transistors since the polycrystalline silicon layers have high field effect mobility and allow for high-speed operating circuits and formation of complementary metal-oxide-semiconductor (CMOS) circuits. Thin film transistors having the polycrystalline silicon layers are mainly used for active devices of active-matrix liquid crystal display (AMLCD) devices, and switching and driving devices of active-matrix organic light emitting diode (AMOLED) display devices.

Examples of methods of crystallizing amorphous silicon into polycrystalline silicon include solid phase crystallization (SPC), excimer laser crystallization (ELC), metal-induced crystallization (MIC), and metal-induced lateral crystallization (MILC) methods. In the SPC method, an amorphous silicon layer is annealed for several to several tens of hours at a temperature of about 700° C. or less, which is a thermal deformation temperature of glass forming a substrate of a display device using a thin film transistor. In the ELC method, an excimer laser is applied to an amorphous silicon layer to locally heat the amorphous silicon layer for a very short period of time at a high temperature. In the MIC method, a crystallization-inducing metal, such as nickel, palladium, gold, or aluminum, is in contact with or injected into an amorphous silicon layer to induce a phase change to a polycrystalline silicon layer. In the MILC method, silicide, produced by reacting a crystallization-inducing metal with silicon, laterally propagates through the amorphous silicon to sequentially induce crystallization of the amorphous silicon layer.

However, the SPC method requires a long processing time, and may cause deformation of a substrate due to long annealing at a high temperature, and the ELC method requires high-priced laser equipment and has poor interface characteristics between a semiconductor layer and a gate insulating layer due to protrusions occurring on a resultant polycrystalline silicon surface.

Research into methods of crystallizing an amorphous silicon layer using a crystallization-inducing metal has been widely conducted because of faster crystallization at a lower temperature than the SPC method. Examples of these crystallization methods using a crystallization-inducing metal include MIC, MILC, and super grain silicon (SGS) crystallization methods.

In the crystallization methods using a crystallization-inducing metal, an amorphous silicon layer is formed using a source gas including a silicon atom and a carrier gas, such as argon gas. However, when argon gas is used as a carrier gas, charge mobility of a polycrystalline silicon layer is not significantly improved.

### SUMMARY OF THE INVENTION

Aspects of the present invention provide a method of forming a polycrystalline silicon layer by a crystallization method using a crystallization-inducing metal, in which hydrogen gas is used as a carrier gas to form an amorphous silicon layer, and thus charge mobility of a crystallized polycrystalline silicon layer can be improved.

According to an embodiment of the present invention, a method of forming a polycrystalline silicon layer includes forming an amorphous silicon layer on a substrate using a gas including a silicon atom and hydrogen gas, and crystallizing the amorphous silicon layer into a polycrystalline silicon layer using a crystallization-inducing metal.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIGS. 1A to 1D are cross-sectional views illustrating a method of forming a polycrystalline silicon layer according to an exemplary embodiment of the present invention; and

FIGS. 2A to 2C are cross-sectional views illustrating a process of fabricating a top-gate thin film transistor according to an exemplary embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures. It will be understood that when an element such as a layer, film, region, or substrate is referred to as being “formed on” or “disposed on” another element, it can be disposed directly on the other element, or intervening elements may also be present. In contrast, when an element is referred to as being “formed directly on” or “disposed directly on” another element, there are no intervening elements present.

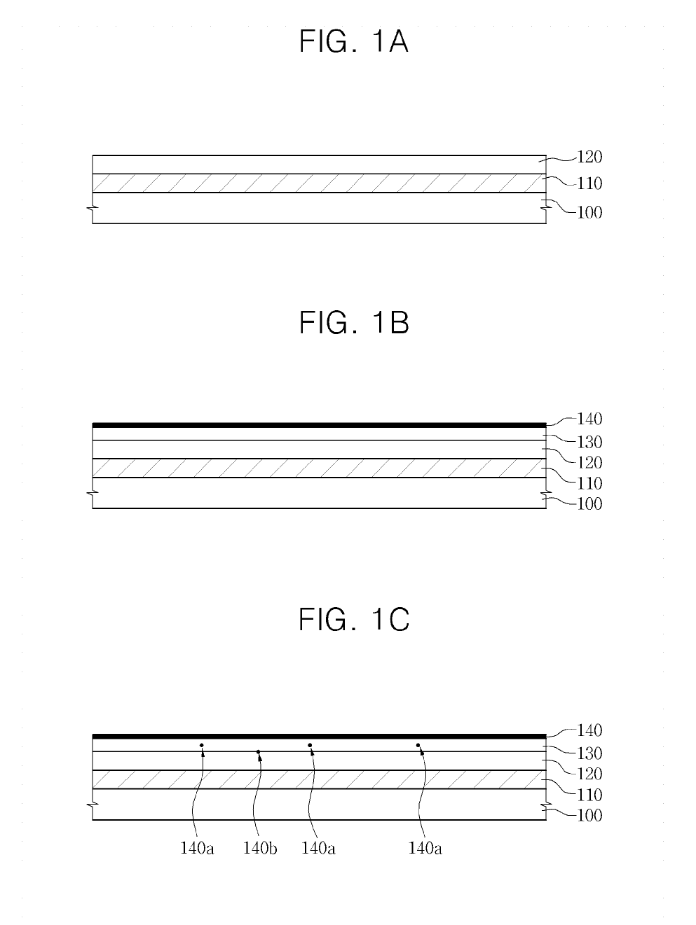

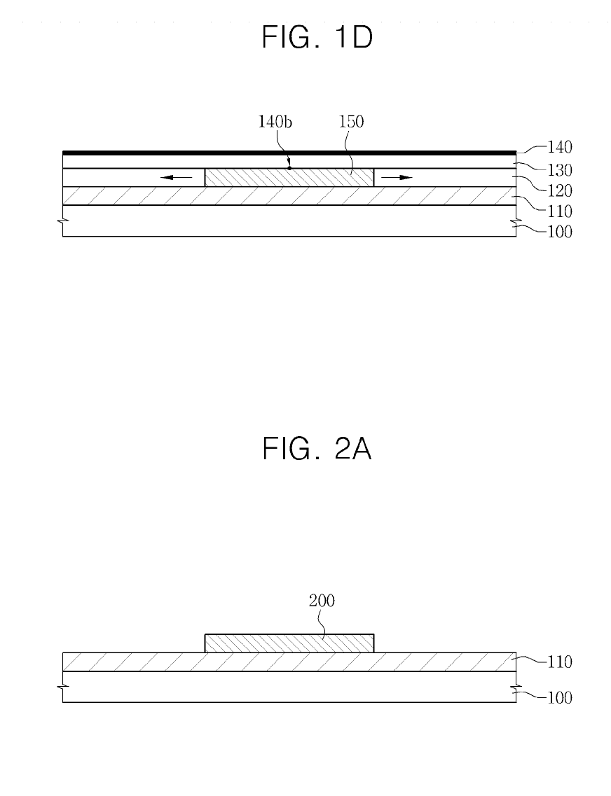

FIGS. 1A to 1D are cross-sectional views illustrating a method of forming a polycrystalline silicon layer according to an exemplary embodiment of the present invention. Referring to FIG. 1A, a substrate 100 formed of glass or plastic is prepared. A buffer layer 110 may be formed on the substrate 100. The buffer layer 110 may be formed of a single layer including silicon oxide or silicon nitride, or a multilayer thereof by chemical vapor deposition (CVD) or physical vapor deposition (PVD). Here, the buffer layer 110 may prevent diffusion of moisture or impurities generated from the substrate 100, or control a heat transfer rate during crystallization to facilitate the crystallization of an amorphous silicon layer.

Subsequently, an amorphous silicon layer 120 is formed on the buffer layer 110. The amorphous silicon layer 120 is formed by chemical vapor deposition (CVD). Examples of CVD may include atmospheric pressure CVD (APCVD), low pressure CVD (LPCVD), low temperature CVD (LTCVD), high temperature CVD (HTCVD), and plasma enhanced CVD (PECVD). For example, PECVD may be used.

The amorphous silicon layer 120 is formed by CVD using a gas including a silicon atom as a source gas and hydrogen gas as a carrier gas. The gas having a silicon atom may be monosilane (SiH₄) gas, disilane (Si₂H₆) gas, tetrachlorosilane (SiCl₄) gas, dichlorosilane (SiH₂Cl₂) gas, tetrafluorosilane (SiF₄) gas, or difluorosilane (SiH₂F₂) gas, or combinations thereof.

A flow rate of the hydrogen gas may be 3 to 7 times larger than a flow rate of the gas having a silicon atom. When the flow rate of the hydrogen gas is less than 3 times or more than 7 times larger than the flow rate of the gas having a silicon atom, crystallization may not be properly performed. For example, when the flow rate of the hydrogen gas is less than 3 times larger than the flow rate of the gas having a silicon atom, a coarse amorphous silicon layer may be formed due to a high deposition rate, and nano-sized microcrystalline silicon may be mixed with amorphous silicon. In addition, when the flow rate of the hydrogen gas is more than 7 times larger than the flow rate of the gas having a silicon atom, a micro-sized microcrystalline silicon layer is mainly formed rather than an appropriate amorphous silicon layer.

The nano- and micro-sized microcrystalline silicons are in a metastable state, which have a lower degree of amorphism than the amorphous silicon. The microcrystalline silicon requires a higher energy than the amorphous silicon due to recrystallization of solid-phase silicon, which may adversely affect crystallization via an SGS method, which will be described later. Here, the amorphous silicon layer 120 may be formed to a thickness of 300 to 1000 Å.

The amorphous silicon layer 120 is crystallized into a polycrystalline silicon layer using a crystallization-inducing metal. Examples of crystallization methods using a crystallization-inducing metal include MIC, MILC, and SGS methods.

In the MIC method, a crystallization-inducing metal such as Ni, Pd, or Al is placed in contact with or injected into an amorphous silicon layer to induce a phase change to a polycrystalline silicon layer; and in the MILC method, silicide, produced by reacting a crystallization-inducing metal with silicon, laterally propagates through the amorphous silicon to sequentially induce crystallization of the amorphous silicon layer.

In the SGS method, the size of a grain can be controlled to be several to several hundreds of μm by decreasing the concentration of a crystallization-inducing metal that diffuses to an amorphous silicon layer. In an exemplary embodiment for reducing the concentration of the crystallization-inducing metal that diffuses to the amorphous silicon layer, a capping layer may be formed on the amorphous silicon layer, a crystallization-inducing metal layer may be formed on the capping layer, and the substrate may be annealed to diffuse the crystallization-inducing metal through the capping layer. Alternatively, the concentration of the diffused crystallization-inducing metal may be reduced by forming the crystallization-inducing metal layer at a low concentration without forming the capping layer.

According to the exemplary embodiment of the present invention, rather than the MIC or MILC method, the SGS method which can reduce the concentration of the crystallization-inducing metal diffused to the amorphous silicon layer by forming the capping layer is preferable, which will be described below. Referring to FIG. 1B, a capping layer 130 is formed on the amorphous silicon layer 120. The capping layer 130 may be formed of silicon nitride, silicon oxide, or a combination thereof. The capping layer 130 may be formed by CVD or PVD, or by thermally oxidizing the amorphous silicon layer 120. The capping layer 130 may be formed to a thickness of 1 to 2000 Å. The thickness of the capping layer 130 is less than 1 Å, an amount of the crystallization-inducing metals that diffuses from the capping layer 130 may be difficult to control; and when the thickness of the capping layer 130 is more than 2000 Å, an amount of the crystallization-inducing metals that diffuses to the amorphous silicon layer 120 may be too small to crystallize the amorphous silicon layer 120 into a polycrystalline silicon layer.

Subsequently, a crystallization-inducing metal layer 140 is formed by depositing a crystallization-inducing metal on the capping layer 130. Here, the crystallization-inducing metal may be one selected from the group consisting of nickel (Ni), palladium (Pd), titanium (Ti), silver (Ag), gold (Au), aluminum (Al), tin (Sn), antimony (Sb), copper (Cu), cobalt (Co), molybdenum (Mo), terbium (Tb), rubidium (Ru), rhodium (Rh), cadmium (Cd), and platinum (Pt), and may be, for example, Ni. The crystallization-inducing metal layer 140 may be formed to have an areal density of 10¹¹ to 10¹⁵ atoms/cm² on the capping layer 130. When the crystallization-inducing metal layer has an areal density less than 10¹¹ atoms/cm², an amount of seeds, i.e., crystallization cores, may be too small to crystallize the amorphous silicon layer 120 into a polycrystalline silicon layer by the SGS method. When the crystallization-inducing metal layer has an areal density more than 10¹⁵ atoms/cm², an amount of the crystallization-inducing metals that diffuses to the amorphous silicon layer 120 is large, and thus a grain of the polycrystalline silicon layer may become smaller. Moreover, as an amount of the crystallization-inducing metals remaining in a semiconductor layer is increased, characteristics of a later-formed semiconductor layer may deteriorate.

The crystallization-inducing metal layer 140 may be formed having a uniform thickness and a low concentration by sputtering, vapor phase deposition, ion beam deposition, electron beam deposition, laser ablation, or atomic layer deposition.

Referring to FIG. 1C, the substrate 100 having the buffer layer 110, the amorphous silicon layer 120, the capping layer 130, and the crystallization-inducing metal layer 140 is annealed, and thus some of the crystallization-inducing metals of the crystallization-inducing metal layer 140 migrate to a surface of the amorphous silicon layer 120. During annealing of the substrate 100, crystallization-inducing metals 140b of crystallization-inducing metals 140a and 140b diffuse through the capping layer 130 to the surface of the amorphous silicon layer 120, and the crystallization-inducing metals 140a do not reach the amorphous silicon layer 120 or do not pass through the capping layer 130.

Thus, the amount of the crystallization-inducing metals reaching the surface of the amorphous silicon layer 120 is dependent on a diffusion-preventing ability of the capping layer 130, which has a close relationship with the thickness or density of the capping layer 130. For example, as the thickness or density of the capping layer 130 increases, the amount of metal that diffuses therethrough is decreased, thereby increasing the size of a grain in the resultant polycrystalline layer. And, as the thickness or density of the capping layer 130 decreases, the amount of metal that diffuses therethrough is increased, thereby decreasing the size of a grain.

The annealing process is performed in the range of about 200 to about 900° C. for about several seconds to hours to diffuse the crystallization-inducing metals. In such temperature and time ranges, deformation of the substrate due to excessive annealing may be prevented, and reduction of production costs and improved yield may be obtained. The annealing process may be performed using one of a furnace process, a rapid thermal annealing (RTA) process, a UV process, and a laser process (i.e., the furnace process, the rapid thermal annealing (RTA) process, the UV process, or the laser process).

Referring to FIG. 1D, the amorphous silicon layer 120 is crystallized into a polycrystalline silicon layer 150 using the crystallization-inducing metals 140b that diffused to the surface of the amorphous silicon layer 120 through the capping layer 130. That is, the amorphous silicon layer 120 is crystallized into the polycrystalline silicon layer 150 by combining the diffused crystallization-inducing metal 140b with the silicon of the amorphous silicon layer 120 to form a metal silicide, and forming a seed, which is a crystallization core, using the metal silicide.

In FIG. 1D, the annealing process is performed without removing the capping layer 130 and the crystallization-inducing metal layer 140. However, after the crystallization-inducing metal 140b is diffused to the surface of the amorphous silicon layer 120 to form the metal silicide, i.e., the crystallization core, the capping layer 130 and the crystallization-inducing metal layer 140 may be removed, and the substrate may be annealed, thereby forming a polycrystalline silicon layer 150.

Meanwhile, in the present exemplary embodiment, the crystallization-inducing metal layer 140 is formed on the amorphous silicon layer 120 (i.e., the amorphous silicon layer 120 is formed on the substrate 100 and the crystallization-inducing metal layer 140 is formed on the amorphous silicon layer), but the crystallization-inducing metal layer 140, the capping layer 130, and the amorphous silicon layer 120 may be sequentially formed on the substrate 100 (i.e., the crystallization-inducing metal layer 140 may be formed on the substrate 100, and the amorphous silicon layer 120 may be formed on the crystallization-inducing metal layer 140), and the amorphous silicon layer 120 may be formed into the polycrystalline silicon layer 150 using crystallization-inducing metals diffused from the underlying layers.

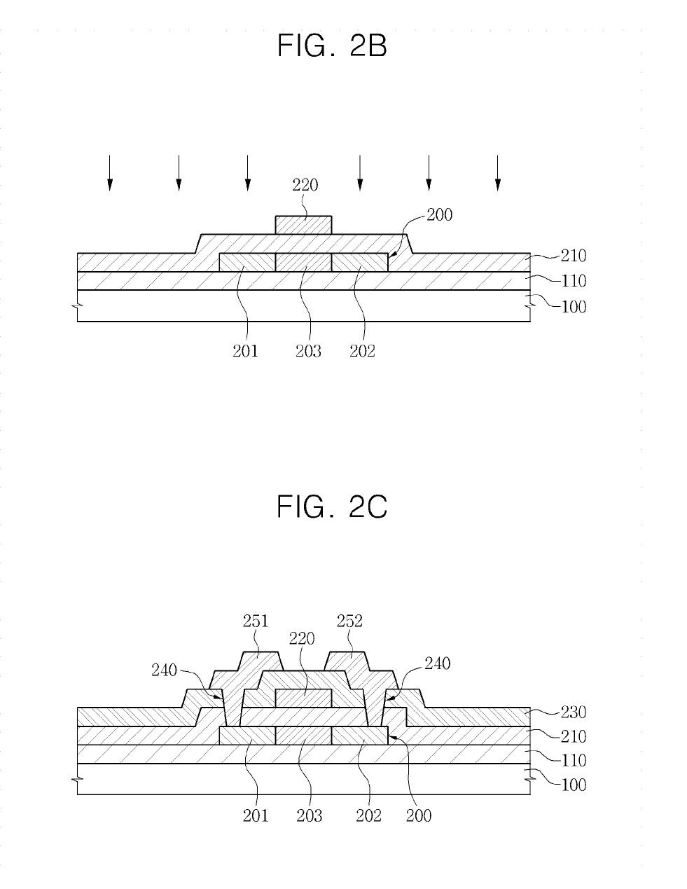

FIGS. 2A to 2C are cross-sectional views illustrating a process of fabricating a top-gate thin film transistor using a method of forming a polycrystalline silicon layer according to an exemplary embodiment of the present invention. Except for particular description below, the process is the same as described with reference to FIG. 1.

Referring to FIG. 2A, a polycrystalline silicon layer is formed on a substrate as described with reference to FIGS. 1A to 1D, and then the crystallization-inducing metal layer 140 and the capping layer 130 are removed. Subsequently, the polycrystalline silicon layer 150 is patterned. The patterned polycrystalline silicon layer becomes a semiconductor layer 200 of a thin film transistor.

Referring to FIG. 2B, a gate insulating layer 210 is formed on the entire surface of the substrate or formed to at least to cover the semiconductor layer 200. The gate insulating layer 210 may be formed of silicon oxide, silicon nitride, or a combination thereof. Subsequently, a metal layer (not shown) for a gate electrode is formed of a single layer of Al or an Al alloy, such as Al—Nd, or a multilayer formed by stacking an Al alloy on a Cr or Mo alloy on the gate insulating layer 210, and then etched to form a gate electrode 220 at a portion corresponding to or above a channel region 203 of the semiconductor layer 200.

After that, source and drain regions 201 and 202 are formed by doping conductive impurity ions using the gate electrode 220 as a mask. The impurity ion may be a p-type or an n-type impurity. The p-type impurity may be one selected from the group consisting of boron (B), aluminum (Al), gallium (Ga), and indium (In), and the n-type impurity may be one selected from the group consisting of phosphorus (P), antimony (Sb), and arsenic (As). Here, a region, which is not doped with an impurity, between the source and drain regions 201 and 202 is the channel region 203. The doping process may be performed by forming a photoresist before forming the gate electrode 220 but is not limited thereto.

Referring to FIG. 2C, an interlayer insulating layer 230 is formed on the entire surface of the substrate 100 having the gate electrode 220 or formed to at least cover the gate electrode 220. The interlayer insulating layer 230 may be formed of silicon nitride, silicon oxide, or a combination thereof.

Contact holes 240 exposing the source and drain regions 201 and 202 of the semiconductor layer 200 may be formed by etching the interlayer insulating layer 230 and the gate insulating layer 210. Subsequently, source and drain electrodes 251 and 252 connected to the source and drain regions 201 and 202 through the contact holes 240 are formed. The source and drain electrodes 251 and 252 may be formed of one selected from the group consisting of Mo, Cr, W, Al—Nd, Ti, MoW, and Al. Thus, a top-gate thin film transistor having the semiconductor layer 200, the gate electrode 220, and the source and drain electrodes 251 and 252 is completed.

Although, a top-gate thin film transistor is described, a bottom-gate thin film transistor may be formed according to aspects of the present invention.

Hereinafter, experimental examples will be provided to help understanding of the aspects of the present invention. However, these experimental examples are provided only to help with understanding and not to limit the aspects of the present invention.

### Experimental Example

A substrate having a buffer layer was disposed in a PECVD apparatus. A power of

100W was applied to the PECVD apparatus, SiH₄ gas at a flow rate of 400 sccm as a source gas and hydrogen gas at a flow rate of 2000 sccm as a carrier gas were provided to the PECVD apparatus to form an amorphous silicon layer to a thickness of 500 Å. A silicon nitride layer was formed to a thickness of 100 Å as a capping layer on the amorphous silicon layer. Nickel was formed as a crystallization-inducing metal layer to have an areal density of 1×10¹³ atoms/cm² on the capping layer. Subsequently, the substrate was annealed to crystallize the amorphous silicon layer into a polycrystalline silicon layer.

### Comparative Example

The Comparative Example was formed using the same process as the Experimental Example, except that argon gas was used as the carrier gas instead of the hydrogen gas.

Table 1 shows surface roughness of the amorphous silicon layers and charge mobility of the crystallized polycrystalline silicon layers according to Experimental and Comparative Examples.

TABLE 1

| | | Charge Mobility |
|---|---|---|
| | Surface Roughness (Å) | (cm²/V · sec) |
| Experimental Example | 11.3 | 64.7 |
| Comparative Example | 21.3 | 36.5 |

Referring to Table 1, during formation of the amorphous silicon layer, it can be confirmed that when the amorphous silicon layer was formed using the hydrogen gas, rather than the argon gas, as a carrier gas, the surface roughness of the amorphous silicon layer was decreased by about 53%. In addition, when the amorphous silicon layer was crystallized into the polycrystalline silicon layer using a crystallization-inducing metal catalyst, the charge mobility of the polycrystalline silicon layer formed using the hydrogen gas as a carrier gas was increased by about 28.2 cm²/V·sec compared to that of the polycrystalline silicon layer formed using the argon gas as a carrier gas.

Consequently, in the method of forming a polycrystalline silicon layer using a crystallization-inducing metal, when the hydrogen gas is used as a carrier gas to form an amorphous silicon layer, the charge mobility of the crystallized polycrystalline silicon layer may be significantly increased. When hydrogen gas is used as a carrier gas to form an amorphous silicon layer during crystallization using a crystallization-inducing metal, charge mobility of a crystallized polycrystalline silicon layer can be improved.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A method of forming a polycrystalline silicon layer, the method comprising:
forming an amorphous silicon layer on a substrate by chemical vapor deposition (CVD) using a gas including a silicon atom and hydrogen gas; and
crystallizing the amorphous silicon layer into a polycrystalline silicon layer using a crystallization-inducing metal.

2. The method of claim 1, wherein a flow rate of the hydrogen gas is 3 to 7 times larger than a flow rate of the gas including the silicon atom.

3. The method of claim 1, wherein the crystallizing of the amorphous silicon layer into the polycrystalline silicon layer using the crystallization-inducing metal comprises:
forming a capping layer on the amorphous silicon layer;
forming a crystallization-inducing metal layer on the capping layer; and
annealing the substrate.

4. The method of claim 1, wherein the crystallizing of the amorphous silicon layer into the polycrystalline silicon layer using the crystallization-inducing metal comprises:
forming a crystallization-inducing metal layer on the substrate;
forming a capping layer on the crystallization-inducing metal layer;
forming the amorphous silicon layer on the capping layer; and
annealing the substrate.

5. The method of claim 3, wherein the crystallization-inducing metal layer is formed to have an areal density of 10¹¹ to 10¹⁵ atoms/cm².

6. The method of claim 4, wherein the crystallization-inducing metal layer is formed to have an areal density of 10¹¹ to 10¹⁵ atoms/cm².

7. The method of claim 1, wherein the crystallization-inducing metal is formed on the amorphous silicon layer by atomic layer deposition.

8. The method of claim 1, wherein the amorphous silicon layer is formed by plasma enhanced CVD.

9. The method of claim 1, wherein the gas including the silicon atom comprises monosilane (SiH₄) gas, disilane (Si₂H₆) gas, tetrachlorosilane (SiCl₄) gas, dichlorosilane (SiH₂Cl₂) gas, tetrafluorosilane (SiF₄) gas, or difluorosilane (SiH₂F₂) gas, or combinations thereof.

10. The method of claim 1, wherein the forming of the amorphous silicon layer comprises:
forming the amorphous silicon layer to a thickness of about 300 to about 1000 Å.

11. The method of claim 1, further comprising:
forming a buffer layer on the substrate,
wherein the amorphous silicon layer is formed on the buffer layer.

12. The method of claim 1, wherein the amorphous silicon layer is formed by one of atmospheric pressure CVD, low pressure CVD, low temperature CVD, high temperature CVD, and plasma enhanced CVD.

13. The method of claim 1, wherein the crystallizing of the amorphous silicon layer comprises:
forming a crystallization-inducing metal layer on the amorphous silicon layer by sputtering, vapor phase deposition, ion beam deposition, electron beam deposition, laser ablation, or atomic layer deposition.

14. The method of claim 1, wherein the crystallizing of the amorphous silicon layer comprises:
metal-induced crystallization (MIC), metal-induced lateral crystallization (MILC), or super grain silicon (SGS) crystallization.

15. The method of claim 1, wherein the crystallization-inducing metal is Ni, Pd, Ti, Ag, Au, Sn, Sb, Cu, Co, Mo, Tb, Ru, Rh, Cd, Pt, or Al.

16. The method of claim 1, the crystallizing of the amorphous silicon layer comprises annealing the substrate and amorphous silicon layer at a temperature about 200 to about 900° C.

17. The method of claim 1, wherein the forming of the amorphous silicon layer comprises:
forming the amorphous silicon layer to a surface roughness of about 11.3 Å.

18. A method of forming a thin film transistor, the method comprising:
forming an amorphous silicon layer on a substrate by chemical vapor deposition (CVD) using a gas including a silicon atom and hydrogen gas; and
crystallizing the amorphous silicon layer into a polycrystalline silicon layer using a crystallization-inducing metal;
patterning the polycrystalline silicon layer into a semiconductor layer;
forming a gate insulating layer on the semiconductor layer;
forming a gate electrode on the gate insulating layer above a channel region of the semiconductor layer;
forming an interlayer insulating layer to cover the gate electrode; and
forming source and drain electrode connected to source and drain regions, respectively, of the semiconductor layer.

19. The method of claim 18, wherein the gas including the silicon atom comprises monosilane (SiH₄) gas, disilane (Si₂H₆) gas, tetrachlorosilane (SiCl₄) gas, dichlorosilane (SiH₂Cl₂) gas, tetrafluorosilane (SiF₄) gas, or difluorosilane (SiH₂F₂) gas, or combinations thereof.

20. The method of claim 18, wherein a flow rate of the hydrogen gas is 3 to 7 times larger than a flow rate of the gas including the silicon atom.
